(19) United States
(12) Patent Application Publication
(10) Pub. No.: US 2025/0110173 A1
(43) Pub. Date: Apr. 3, 2025

(54) METHODS, SYSTEMS, ARTICLES OF MANUFACTURE, AND APPARATUS FOR IMPROVED THERMAL TESTS OF INTEGRATED CIRCUIT DEVICES

(71) Applicant: Intel Corporation, Santa Clara, CA (US)

(72) Inventor: Gregorio R. Murtagian, Phoenix, AZ (US)

(21) Appl. No.: 18/477,360

(22) Filed: Sep. 28, 2023

(51) Int. Cl. G01R 31/28; G01K 1/22; G01K 1/26

(52) U.S. Cl. CPC G01R 31/287; G01K 1/22; G01K 1/26; G01R 31/2862; G01R 31/2874; G01R 31/2896

(57) ABSTRACT

Systems, apparatus, articles of manufacture, and methods are disclosed that improve thermal tests of integrated circuit devices. An example apparatus includes interface circuitry; machine readable instructions; and programmable circuitry to at least one of instantiate or execute the machine readable instructions to determine a condition of a fluid to be dispensed by a pneumatic nozzle, the condition of the fluid including a temperature of the fluid; determine a ratio of a first liquid, a second liquid, and a superheated vapor that combine to result in the condition of the fluid; and cause the first liquid, the second liquid, and the superheated vapor to be provided to the pneumatic nozzle in proportions defined by the ratio.

### FIELD OF THE DISCLOSURE

This disclosure relates generally to integrated circuit (IC) packages and, more particularly, to methods, systems, articles of manufacture, and apparatus to improve thermal tests of integrated circuit devices.

### BACKGROUND

In many integrated circuit (IC) packages, one or more semiconductor dies are mechanically and electrically coupled to an underlying package substrate, which can have an array of pins, pads, solder balls, and/or lands to enable the electrical coupling of the dies with a motherboard or printed circuit board. Semiconductor dies are subjected to a variety of tests after manufacture and before shipping. During class testing of semiconductor dies, individual units are binned based on their performance. The reliability of such tests depend on maintaining the temperature of the testing procedure within relatively narrow limits. Maintaining temperature can be difficult because different parts of the test program can lead to significant variations in power dissipation in a relatively short time period (e.g., on the order of hundred milliseconds).

### BRIEF DESCRIPTION OF THE DRAWINGS

FIG. 1 is a schematic illustration of an example environment for testing integrated circuit (IC) devices in accordance with teachings of this disclosure.

FIG. 2 is a cross-sectional view of an example nozzle for thermal control constructed in accordance with teachings disclosed herein.

FIG. 3 is a block diagram of an example implementation of the control circuitry of FIG. 1.

FIG. 4 is a flowchart representative of example machine readable instructions and/or example operations that may be executed, instantiated, and/or performed by example programmable circuitry to implement the control circuitry of FIG. 3.

FIG. 5 is a block diagram of an example processing platform including programmable circuitry structured to execute, instantiate, and/or perform the example machine readable instructions and/or perform the example operations of FIG. 4 to implement the control circuitry of FIG. 3.

FIG. 6 is a block diagram of an example implementation of the programmable circuitry of FIG. 5.

FIG. 7 is a block diagram of another example implementation of the programmable circuitry of FIG. 5.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified in the below description.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

### DETAILED DESCRIPTION

IC devices (e.g., IC packages, semiconductor die(s) in IC packages, etc.) are subjected to a variety of tests after manufacture and before shipping. Such tests may be conducted before the devices are packaged and/or after the devices are packaged. During a semiconductor class test (e.g., test/sort process), for example, maintaining accurate and stable semiconductor die temperature is important to correctly bin products based on their performance. Tested units can have significant variations in the rate of power dissipation (of the order of hundred milliseconds). Despite this variation across different units, reliable test results need the units to maintain a test temperature within relatively narrow limits (e.g., +/−10° C. in some examples). The ability to maintain a relatively constant test temperature with sudden changes of dissipated power (e.g., based on the thermal solution time response) is important for product performance testing.

In the past, a relatively wide range of temperatures are permitted when testing IC devices (e.g., semiconductor dies) to enable the test to be carried out for devices with a relatively slow thermal solution time response. However, allowing for relatively large thermal variability during testing can under-stress or over-stress a semiconductor dies. This can lead to false or inaccurate test results with detrimental effects such as (but not limited to) an increase in field failure rates (e.g., defects per million (DPM)), additional manufacturing yield loss, etc. In other words, an inability to quickly control temperature leads to testing across a wider temperature range, leading to a less reliable test.

Another potential approach to maintain temperatures during semiconductor die testing is with the use of a predictive power response (PPR) control method. The PPR control method includes extending test time to accommodate for slower thermal solution time response systems. More particularly, the PPR control method extends the test time by effectively halting execution of the test to allow for a given thermal solution to cool down a semiconductor die being tested and/or set the control conditions to dissipate higher power levels. In other words, using PPR includes halting the test execution to bring the semiconductor die to a target temperature, and then continuing the test under specific control conditions. However, utilizing a PPR control method to accommodate a slow thermal system time response can greatly increase test costs, reduce throughput, and/or generally reduce revenue.

Another potential approach to maintain temperatures during semiconductor die testing involves the implementation of zero-parasitic element cooling (ZPEC), which involves the testing of a semiconductor die within a pressure-controlled chamber in which two-phase cooling is utilized to draw heat from the semiconductor devices. Two-phase cooling involves a cooling fluid (e.g., water) changing from the liquid phase to the cooling phase. Changing phases in this manner requires significant amounts of heat, which can be taken from the semiconductor dies. For such heat transfer to be done efficiently, the liquid water dispensed on the semiconductor dies needs to be at, above, or close to the saturation temperature corresponding to the pressure of the chamber so that the water does not need to take time to heat before transitioning to the vapor phase. Accordingly, the ZPEC method controls the saturation temperature by modifying the pressure in the pressure-controlled chamber. Specifically, in some instances, large volumes of air volume can be added through an air stent to quickly increase the pressure in the chamber. Due to the increase in pressure, the water saturation temperature in the chamber also increases. In this case, the ZPEC method is utilized to increase the set point temperature. In some instances, a pressure in the chamber is reduced by a vacuum pump. Further, the pressure within the chamber can be modulated by a valve at a vapor-out line. By reducing the pressure within the pressure-controlled chamber, the water saturation temperature is lowered, thereby causing fluid (e.g., water) entering the chamber at an elevated (e.g., superheated) temperature (e.g., slightly above 100 degrees Celsius (° C.)) to boil and/or evaporate to become vapor. Such vaporization of the fluid reduces the temperature of the remaining fluid (to the saturation temperature), which helps remove heat from the semiconductor die being tested at the faster rate. Typically, the fluid (e.g., water) is introduced to the pressure-controlled chamber through a hydraulic nozzle that causes the fluid to spray into the chamber on onto the semiconductor die to be cooled. In such instances, the force (e.g., the dispensing energy) with which the fluid is sprayed (e.g., atomized) into the chamber is driven by the pressure of the fluid itself being provided to the nozzle.

As outlined above, modulation of the pressure enables modulation of the saturation temperature. A relatively higher pressure results in a relatively higher saturation temperature, and a reduction in heat removal. When the water saturation temperature of the fluid needs to be quickly increased in the chamber, the air stent can introduce a (e.g., large) volume of air to increase a pressure within the chamber. When the fluid enters the chamber, adiabatic fluid expansion occurs. This results in a decrease in a fluid temperature from a saturation temperature to an evaporation temperature, and an increase to a heat transfer coefficient of the semiconductor die (e.g., flash heat transfer). This ZPEC method for controlling temperature during semiconductor die testing requires additional hardware relative to other approaches that are relatively costly and add complexity to the testing system. In particular, the ZPEC method requires a relatively large vacuum pump capacity (e.g., to remove air and reduce pressure), an air stent (e.g., to introduce air and increase pressure), and an air/vapor separator (e.g., to separate the air and the vaporized liquid for reuse in the system). Moreover, in some instances, the ZPEC method does not provide a thermal response that is fast enough to maintain the temperature of certain semiconductor dies within the relatively narrow thermal limits for more reliable test results.

Examples disclosed herein enable high speed, controllable, and accurate thermal solution test systems for semiconductor die class testing. Example thermal solution test systems disclosed herein maintain a relatively constant test temperature with sudden changes of dissipated power (e.g., for rapid thermal solution time response).

Unlike the ZPEC method that relies on a hydraulic (e.g., fluid-based) nozzle to dispense cooling fluid (e.g., water) into the testing chamber, example thermal solution test systems disclosed herein include one or more example pneumatic (e.g., gas-based) nozzles structured to provide a relatively fast thermal solution time response. Examples pneumatic nozzles disclosed herein are coupled to a superheated vapor source, enabling the pneumatic nozzles to dispense superheated vapor into a pressure-controlled chamber. Further, examples pneumatic nozzles disclosed herein are coupled to one or more liquid sources, enabling the pneumatic nozzles to dispense the fluid from the one or more liquid sources into a pressure-controlled chamber. For example, the pneumatic nozzle can be configured to dispense a relatively hot liquid and/or a relatively cold liquid.

In particular, example pneumatic nozzles disclosed herein are structured to combine a relatively hot liquid and a relatively cold liquid. In some examples, the relatively hot liquid and the relative cold liquid are combined at the nozzle inlet. In some examples, the relatively hot liquid and/or the relatively cold liquid includes water. In some examples, the relatively hot liquid and/or the relatively cold liquid are mixed with the superheated vapor to achieve an overall mass and energy balance at an outlet of the pneumatic nozzle. In other words, a mass and energy balance is achieved by controlling a ratio of hot liquid, cold liquid, and superheated vapor to meet operational requirements. In some examples, the hot and/or cold liquid supply lines can be closed, allowing the superheated vapor to fill the chamber without the liquid to (e.g., rapidly) increase a temperature of the semiconductor die under test.

In some examples, the pneumatic nozzle uses the superheated vapor to heat the liquid to a target temperature. In some examples, the target temperature of the liquid is above (e.g., approximately 3-10 degrees above) the saturation temperature associated with the chamber pressure. In some examples, the pneumatic nozzle uses the superheated vapor to pulverize or atomize the liquid. In other words, the superheated vapor can be utilized as means for heating and/or atomizing the liquid.

Example pneumatic nozzles disclosed herein (that rely on a pressurized gas (e.g., the superheated vapor) to facilitate the dispensing or ejection of liquid (e.g., the hot and/or cold liquids)) provide more kinetic energy to fluid spray droplets (e.g., the atomized fluid) relative to previous hydraulic nozzles (that rely exclusively on the pressure of the liquid being dispensed through the nozzle). In some examples, a heat transfer coefficient associated with the semiconductor die under test is proportional to an impact velocity of the droplets. As such, the increased kinetic energy achieved through the implementation of a pneumatic nozzle, as disclosed herein, improve a heat transfer coefficient associated with the semiconductor die under test relative to previous solutions, thereby increasing an efficiency of a thermal response control system.

In some examples, the superheated vapor introduced into the chamber and any of the liquid that turned into vapor with the chamber can be removed via an outlet of the chamber for reuse. Unlike the ZPEC method that requires an air/vapor separator to isolate the air for reuse and condense the vapor for reuse in the liquid phase, the superheated vapor in disclosed examples does not need to be condensed, but can be recycled into the system, increasing an energy efficiency of a system relative to past thermal cooling techniques. Examples disclosed herein can increase an amount of correctly binned products to facilitate an increase in average selling price of the semiconductor dies. Examples disclosed herein provide greater reliability in an end-product, higher factory throughput, and reduced manufacturing cost.

As used herein, unless specifically stated otherwise, a liquid(s) refers to one or more liquids (e.g., liquid water, a relatively hot liquid, a relatively cold liquid, etc.), a gas refers to a gas (e.g., superheated water vapor, etc.), and a fluid refers to one or more of the liquid(s) and/or the gas that is to be dispensed into an example pneumatic nozzle and/or that exits an example pressure-controlled chamber disclosed herein.

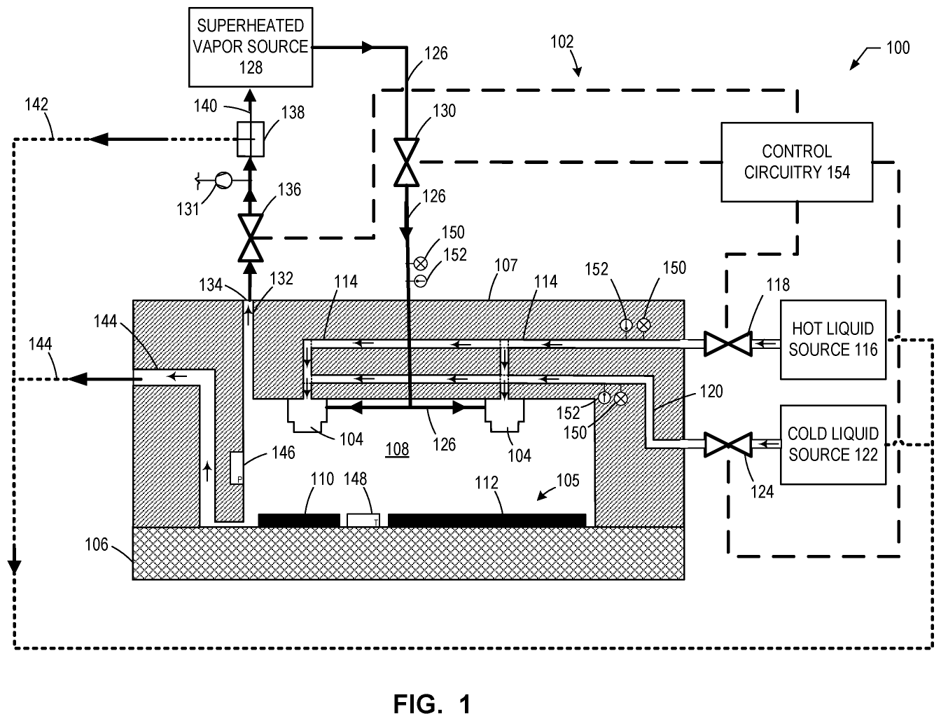

FIG. 1 illustrates an example environment 100 for IC device (e.g., semiconductor die) testing including an example thermal control system 102 having example nozzles 104 constructed in accordance with teachings disclose herein. While two example nozzles 104 are shown in FIG. 1, in other examples, the thermal control system 102 can include only a single nozzle 104. In other examples, the thermal control system 102 includes more than two nozzles 104. In the illustrated example of FIG. 1, arrow lines are provided between various components. The arrow lines represent any type of fluid connection, such as a transport bus, a conduit, a duct, fluid line, a hose, a tube, a connector, a port, and/or other structure or opening that fluidly couples two components. Therefore, any two components with an arrow between them can be considered fluidly coupled.

The thermal control system 102 of FIG. 1 is structured to test the performance of an IC device. In this example, the IC device is an IC package 105 that includes an example package substrate 106 and two example semiconductor dies 110, 112 mounted on the package substrate 106. In this example, the IC package 105 is mounted via the package substrate 106 to a socket or other connector to send and receive test signals and power (not shown) to and from the semiconductor dies 110, 112. In other words, the package substrate 106 is electrically coupled to the socket or other power source, and the semiconductor dies 110, 112 are electrically coupled to the package substrate 106. While two semiconductor dies 110, 112 are illustrated in FIG. 1, examples disclosed are not limited thereto. Rather, any number of semiconductor dies 110, 112 (e.g., only one, more than two) can be tested using the thermal control system 102. The semiconductor dies 110, 112 can provide any suitable type of functionality (e.g., data processing, memory storage, etc.).

In the illustrated example of FIG. 1, the IC package 105 is coupled to a test chamber housing 107 that defines or includes an example pressure-controlled chamber 108. More particularly, in this example, the semiconductor dies 110, 112 are positioned to be within the chamber 108 and to face towards the nozzles 104. During a class test (e.g., a bin test, a quality test, a performance test, etc.), power is applied to the IC package 105 to operate the semiconductor dies 110, 112. Based on one or more factors (e.g., performance, thermal response, etc.), the semiconductor dies 110, 112 are assigned to a particular class (e.g., a fail class, a pass class, a specific category within the pass class, etc.).

As illustrated in FIG. 1, the nozzles 104 are directed towards the semiconductor dies 110, 112 housed within the chamber 108. In particular, each nozzle 104 is directed towards a respective semiconductor die 110, 112. However, the nozzles 104 can be arranged according to a wide variety of configurations in other examples. For example, multiple nozzles 104 can be directed towards a single semiconductor die 110, 112, one nozzle 104 can be directed towards multiple semiconductor dies 110, 112, etc. The nozzles 104 are structured to enable relatively fast thermal control of the semiconductor dies 110, 112 by dispensing a fluid into the pressure-controlled chamber 108 where the semiconductor dies 110, 112 are being tested.

As illustrated in FIG. 1, an example first liquid conduit 114 (e.g., duct, pipeline, channel, etc.) is fluidly coupled between a hot liquid source 116 and the nozzles 104. In this respect, the first liquid conduit 114 is structured to deliver a relatively hot liquid from the hot liquid source 116 to the nozzles 104. In this example, an example first valve 118 is fluidly coupled to the first liquid conduit 114 at a position between the hot liquid source 116 and the nozzles 104. In the illustrated example, the first valve 118 is external to the test chamber housing 107. In other examples, the first valve 118 is included within the test chamber housing 107. In general, the first valve 118 is configured to control the flow of the hot liquid through the first liquid conduit 114. For example, the first valve 118 can control at least one of a flow rate or a volume of the hot liquid to the nozzles 104.

Similarly, an example second liquid conduit 120 (e.g., duct, pipeline, channel, etc.) is fluidly coupled between a cold liquid source 122 and the nozzles 104. In this respect, the second liquid conduit 120 is structured to deliver a relatively cold liquid from the cold liquid source 122 to the nozzles 104. In this example, an example second valve 124 is fluidly coupled to second liquid conduit 120 at a position between cold liquid source 122 and the nozzles 104. In the illustrated example, the second valve 124 is external to the test chamber housing 107. In other examples, the second valve 124 is included within the test chamber housing 107. In general, the second valve 124 is configured to control the flow of the cold liquid through the second liquid conduit 120. For example, the second valve 124 can control at least one of a flow rate or a volume of the cold liquid to the nozzles 104.

In other words, the first and second valves 118, 124 are fluidly coupled to a respective liquid conduit 114, 120 and, as such, the valves 118, 124 can be moved between fully and/or partially opened and/or closed positions to selectively occlude the flow of a respective liquid through its corresponding liquid conduit 114, 120. Consequently, the valves 118, 124 can be used to control the flow of liquid to the nozzles 104. The particular arrangement of the liquid conduits 114, 120 is simplified in the illustrated example for purposes of explanation. Generally speaking, the conduits 114, 120 can have any suitable shape and/or arrangement that enables the hot and cold liquids to be combined in controlled amounts before being introduced to the nozzles 104. Thus, in some examples, the conduits 114, 120 may separate into multiple separate lines and/or various fluid control mechanisms (e.g., check valves) may be includes in the conduits 114, 120 to control the direction and flow of fluid as it travels from the inlet valves 118, 124 towards the nozzles 104.

As illustrated in FIG. 1, an example first gas conduit 126 (e.g., duct, pipeline, channel, etc.) is fluidly coupled between a superheated vapor source 128 and the nozzles 104. In this respect, the first gas conduit 126 is structured to deliver a superheated vapor from the superheated vapor source 128 to the nozzles 104. The superheated vapor adds heat to the fluid dispensed by the nozzles, enabling greater control of temperature. Further, the superheated vapor enables the nozzles 104 to dispense the fluid at higher speeds (e.g., compared to a hydraulic nozzle without a gas line) and with more distribution (e.g., the spray angle from a pneumatic nozzle can be wider than the spray angle for a hydraulic nozzle).

In this example, an example third valve 130 is fluidly coupled to the first gas conduit 126 at a position between the superheated vapor source 128 and the nozzles 104. In general, the third valve 130 is configured to control the flow of the superheated vapor through the first gas conduit 126. For example, the third valve 130 can control at least one of a flow rate or a volume of the superheated vapor to the nozzles 104. The third valve 130 can be moved between fully and/or partially opened and/or closed positions to selectively occlude the flow of the superheated vapor through the first gas conduit 126 and, consequently, can be used control the flow of gas (e.g., vapor) to the nozzles 104. In the illustrated example, the third valve 130 is external to the test chamber housing 107. In other examples, the third valve 130 is included within the test chamber housing 107.

In some examples, the thermal control system 102 includes an example vacuum pump 131 structured to draw gas out of the chamber 108. In particular, the chamber 108 can be depressurized during execution of a test to lower the saturation temperature. In some examples, the vacuum pump 131 is omitted.

As illustrated in FIG. 1, an example outlet conduit 132 (e.g., duct, pipeline, channel, etc.) is fluidly coupled to an example outlet 134 of the chamber 108. The outlet 134 provides an opening through which fluid can exit the chamber 108. An example fourth valve 136 (e.g., a vacuum valve) is fluidly coupled to the outlet conduit 132 adjacent the chamber outlet 134. In general, the fourth valve 136 is configured to allow fluid flow through the chamber outlet 134 (e.g., as pumped by the vacuum pump 131) to reduce a pressure within the chamber 108. In particular, the fourth valve 136 can be moved between fully and/or partially opened and/or closed positions to selectively enable the flow of the fluid through the chamber outlet 134 and to the outlet conduit 132. In the illustrated example, the fourth valve 136 is external to the test chamber housing 107. In other examples, the fourth valve 136 is included within the test chamber housing 107.

In this example, the outlet conduit 132 is fluidly coupled between the chamber outlet 134 and an example separator 138. The separator 138 is structured to separate vapor from liquid as the fluid exits the chamber 108. In this example, an example second gas conduit 140 (e.g., duct, pipeline, channel, etc.) is fluidly coupled between the separator 138 and the superheated vapor source 128. As such, the superheated vapor exiting the chamber 108 does not need to be condensed. Rather, the superheated vapor can be recycled back to the superheated vapor source 128 via the second gas conduit 140, and sent back to the nozzles 104 to increase an energy efficiency of the thermal control system 102.

In some examples, an example third liquid conduit 142 (e.g., duct, pipeline, channel, etc.) is fluidly coupled between the separator 138 and the hot liquid source 116 and/or the cold liquid source 122. In some examples, liquid can be separated from fluid exiting the chamber 108 (e.g., by the separator 138), which can be recycled by the hot liquid source 116 and/or the cold liquid source 122 and sent back to the nozzles 104. In the illustrated example of FIG. 1, the thermal control system 102 includes an example overflow conduit 144 to prevent an excess of liquid from remaining within the chamber 108. In this example, the overflow conduit 144 is fluidly coupled to the third liquid conduit 142. In some examples, the separator 138 can be omitted with liquid in the chamber 108 being extracted through the overflow conduit 144 while vapor is extracted through the outlet conduit 132.

The chamber 108 of this example includes an example chamber pressure sensor 146 structured to measure a pressure within the chamber 108. The chamber pressure sensor 146 enables the thermal control system 102 to determine an operational pressure within the chamber 108 during a test. One or more example temperature sensors 148 are disposed within the chamber 108 and positioned to measure a temperature of the semiconductor dies 110, 112 and/or the ambient temperature within the chamber 108 during a test. In some examples, a separate temperature sensor 148 is employed to monitor the temperature of each semiconductor dies 110, 112. In some examples, multiple temperatures sensors 148 can be used to measure the temperature of a single die 110, 112 (e.g., at different locations on the dies 110, 112). In some examples, the semiconductor dies 110, 112 may include internal temperature sensors that provide an internal temperature of the semiconductor dies 110, 112. In some examples, the thermal control system 102 includes additional or alternative sensors within the chamber 108.

In this example, an example pressure sensor 150 is coupled to each of the first liquid conduit 114, the second liquid conduit 120, and the first gas conduit 126. The pressure sensors 150 are configured to measure a pressure of a fluid flowing through or otherwise housed in a respective conduit 114, 120, 126. The pressure sensors 150 can be any suitable type of pressure sensors to measure a pressure of a fluid within a conduit. Further, an example temperature sensor 152 (e.g., a temperature gauge, etc.) is coupled to each of the first liquid conduit 114, the second liquid conduit 120, and the first gas conduit 126. The temperatures sensors 152 are configured to measure a temperature of a respective fluid. The temperatures sensors 152 can be any suitable type of temperature sensors to measure a temperature of a fluid within a respective conduit. The example pressure sensors 150, and temperature sensors 152 can be located at any suitable location along the respective conduits 114, 120, 126 and need not be located at the positions represented in the illustrated example. For instance, any of the sensors 150, 152 can be included within the test chamber housing 107 or external to the test chamber housing 107. Further, the sensors 150, 152 may be downstream of the associated valves 118, 124, 130 on the associated conduits 114, 120, 126 or upstream of the valves 118, 124, 130. In some examples, sensors can be positioned both upstream and downstream the valves 118, 124, 130.

The thermal control system 102 of FIG. 1 includes example control circuitry 154 (e.g., a controller) to operate, control, and/or communicate with the various devices and control operation of the thermal control system 102. The control circuitry 154 is communicatively coupled to the valve(s) 118, 124, 130, 136, one or more of the sensor(s) 146-152, and/or any other device that controls and/or monitors various parameters of the thermal control system 102. The control circuitry 154 can be communicatively coupled to the different components via wired connections (e.g., Ethernet, coaxial, universal serial bus (USB), etc.) and/or wireless connections (e.g., Bluetooth, cellular, Wi-Fi, near field communication (NFC), etc.).

The control circuitry 154 is structured to cause the valves 118, 124, 130, 136 to open and/or close (or otherwise change an extent of opening) based on temperature(s) and/or pressure(s) associated with the thermal control system 102. In particular, the control circuitry 154 obtains signals (e.g., sensor feedback data) from the one or more sensors 146-152 indicative of a condition of the thermal control system 102. For example, the control circuitry 154 of FIG. 1 is structured to obtain a chamber pressure measurement from the chamber pressure sensor 146, fluid pressure measurements from the pressure sensors 150 coupled to each of the first liquid conduit 114, the second liquid conduit 120, and the first gas conduit 126, and fluid temperature measurements from the temperature sensors 152 coupled to each of the first liquid conduit 114, the second liquid conduit 120, and the first gas conduit 126. In some examples, the control circuitry 154 obtains a temperature measurement(s) of the semiconductor dies 110, 112 and/or the ambient temperature inside the chamber 108 from the temperature sensors 148.

In this example, the die temperature of the semiconductor dies 110, 112 is a function of how much the dies 110, 112 heat up when they are powered and in operation (e.g., performing computational tasks) and how quickly the semiconductor dies 110, 112 dissipate heat to the surrounding environment. How quickly heat produced by the dies 110, 112 dissipates to the surrounding environment depends on the conditions of the surrounding environment and how effectively and/or efficiently the environmental conditions are able to draw heat from the dies 110, 112 based on factors such as a heat transfer coefficient of the semiconductor dies 110, 112, etc. Accordingly, based on the measured conditions (e.g., temperature and pressure) within the chamber 108, measured temperature(s) of the semiconductors dies 110, 112, and a target temperature (e.g., a set point) for the semiconductor dies 110, 112, the control circuitry 154 of FIG. 1 is structured to determine how to adjust the conditions within the chamber 108 to maintain the temperature of the semiconductor dies 110, 112 at (or as close as possible) to the set point temperature. In the context of two-phase cooling systems, this can be achieved by adjusting the pressure in the chamber 108 to adjust the saturation temperature at which the liquid introduced into the chamber 108 will boil (thereby drawing away heat from the semiconductors dies 110, 112). Additionally or alternatively, the control circuitry 154 can adjust the temperature of the fluid (liquid and/or vapor) introduced into the chamber 108 to bring the temperature closer to the saturation temperature (given the pressure in the chamber 108).

That is, in some examples, the control circuitry 154 determines a fluid condition (e.g., temperature and/or pressure) of fluid to be dispensed onto the semiconductor dies 110, 112 by the nozzles 104. Each nozzle 104 includes three inputs: the superheated vapor, the hot liquid, and the cold liquid. Thus, based on the determined condition of the fluid to be dispensed by the nozzles 104, the control circuitry 154 determines a ratio of hot liquid, cold liquid, and superheated vapor to meet operational requirements.

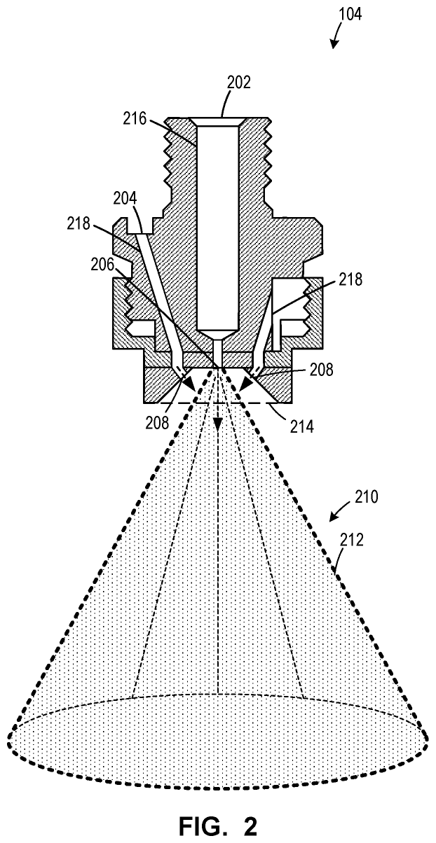

As discussed in further detail below in relation to FIG. 2, the determination is based on a balance of mass and energy. Mass and energy balance is achieved by controlling the ratio of hot liquid, cold liquid, and superheated vapor. For example, two liters of cold liquid at 10° C. with 1 liters of hot liquid a 100° C. will result in 3 liters of liquid a 50° C. The hot liquid and the cold liquid can be combined to generate a combined liquid at a given temperature. The superheated vapor provides kinetic energy and heat, which will be transferred to the combined liquid. The three inputs can be balanced such that the nozzles 104 output a fluid having a specific temperature and a specific speed in response to the current pressure (and associated saturation pressure) in the chamber 108 as well as the measured temperature(s) of the semiconductor dies 110, 112 relative to a target (e.g., set point) temperature.

The hot liquid flow can be controlled by the first valve 118, the cold liquid flow can be controlled by the second valve 124, and the superheated vapor flow can be controlled by the third valve 130 to achieve an overall mass and energy balance. In this example, the valves 118, 124, 130 are controlled by the control circuitry 154. In particular, the control circuitry 154 controls (e.g., actuates) a core (e.g., plunger, disk, diaphragm, ball, globe, gate, etc.) of one or more of the valves 118, 124, 130 to an opened position, a closed position, or a partially opened position based on the target fluid condition. In some examples, the control circuitry 154 completely closes one or more of the valves 118, 124, 130 to block one or more of the hot liquid, the cold liquid, or the superheated vapor from entering the chamber 108 based on the current conditions in the chamber and the measured temperature(s) of the semiconductor dies 110, 112 relative to the set point temperature. Because the superheated vapor can be recycled back to the superheated vapor source 128 via the second gas conduit 140, in some examples, at least a portion of superheated vapor provided to the nozzles 104 includes vapor removed from the chamber 108. Similarly, in some examples, at least a portion of the hot liquid and/or the cold liquid provided to the nozzles 104 includes hot liquid and/or the cold liquid removed from the chamber 108.

In this example, the control circuitry 154 operates as feedback loop. The control circuitry 154 obtains and/or determines an operating temperature of the semiconductor dies 110, 112. When the operating temperature of the semiconductor dies 110, 112 is outside the target temperature (e.g., too high or too low), the control circuitry 154 determines a fluid condition of a fluid to be dispensed by the nozzles 104. In response to determining the fluid condition, the control circuitry 154 is structured to cause the target fluid to dispense onto the semiconductor dies 110, 112 by operating one or more of the valves 118, 124, 130. The control circuitry 154 sends an output signal (e.g., control signal, etc.) to actuate the valve(s) 118, 124, 130 to move a core of the valve(s) 118, 124, 130 to a designated position (e.g., fully open, fully closed, or some intermediate (partially open) position).

FIG. 2 is a cross-sectional view of an example nozzle 104 for thermal control constructed in accordance with teachings of this disclosure. The nozzle 104 includes one or more first (e.g., liquid) inlets 202 and an example second (e.g., gas) inlet 204. In some examples, the nozzle 104 can include two liquid inlets 202 (e.g., a hot liquid inlet and a cold liquid inlet). In some examples, the nozzle 104 can include one liquid inlet 202 that is fluidly coupled to the first liquid conduit 114 and/or the second liquid conduit 120. In the illustrated example (where this is only a single liquid inlet 202), the hot liquid and cold liquid are to be combined upstream of the nozzle 104 (as shown in FIG. 1). The nozzle 104 includes a first (e.g., liquid) outlet 206 and an example second (e.g., gas) outlet 208.

The nozzle 104 is pneumatic (e.g., atomizing) nozzle that dispenses fluid in an atomized spray-like fashion (e.g., as opposed to a hose-like fashion). In particular, the superheated vapor is structured to pulverize or automize the liquid into a high energy (e.g., high speed) spray. As the liquid exits the liquid outlet 206, the liquid is met by the superheated vapor, which breaks the liquid into small droplet particles. The superheated vapor adds kinetic energy to the liquid to provide speed. In some examples, the higher speed of a resultant fluid facilitates improved heat removal because the heat transfer coefficient is proportional to the impact velocity of the droplets.

As illustrated in FIG. 2, an example stream 210 of nozzle spray 212 is dispensed at an example nozzle outlet 214. The nozzle outlet 214 is a portion of the nozzle 104 at which the liquid and the superheated vapor exit the nozzle 104. In other words, the nozzle outlet 214 is a portion of the nozzle 104 that includes the liquid outlet 206 and the gas outlet 208. As shown in the illustrated example, the fluid stream 210 has a cone shaped spray pattern that spreads the fluid stream 210 over a relatively large area circular area. In some examples, this results in more homogenous cooling of a semiconductor die under test than is possible with existing approaches that use nozzles providing a more narrow stream of fluid. Although the spray pattern is a cone in the illustrated example to cover a circular area, any other suitable spray pattern may be implemented (e.g., a flat fan spray pattern, etc.).

The nozzle 104 includes three inputs: cold water (e.g., 70° C. or room temperature), hot water (e.g., at a different, higher temperature), and the supersaturated vapor. In some examples, the temperatures for each of the cold water, hot water, and superheated vapor depends on the operating pressure and the associated saturation temperature inside the chamber. In some examples, the cold water can be at room temperature (e.g., around 20° C.) so that it does not need to be cooled or heated. However, in other examples, the cold water can be cooled to a temperature below room temperature (e.g., less than 15° C., less than 10° C., etc.). In other examples, the cold water may be higher than room temperature. The hot water can be maintained at any suitable temperature greater than cold temperature. In some examples, the temperature of the hot water can be significantly higher than the cold water (e.g., above 70° C., above 90° C., above 100° C.) and potentially as high as 125° C. or more. In some examples, the much higher temperature is selected to be close to (e.g., within 10° C., within 5° C.) of the saturation temperature (e.g., boiling point) of water inside the chamber 108. In some examples, the temperature of the hot water is selected to be above the saturation temperature of water inside the chamber 108. The saturation temperature of water at standard atmospheric pressure is 100° C. Thus, examples that use temperatures for the hot water above 100° C. are based on the hot water being pressurized to increase the saturation temperature of the water. In some examples, the temperature of the superheated vapor is higher than the temperature of the hot water. In some examples, the temperature of the superheated vapor can be any suitable temperature that at least some amount (e.g., at least 5° C., at least 10° C., at least 20° C., etc.) above the saturation temperature of water, which, as noted above, is a function of the pressure in the chamber 108. For instance, in some examples, the superheated vapor is at least 100° C., at least 110° C., at least 120° C., at least 130° C., at least 200° C., etc. The temperature of the superheated vapor is a function of pressure such that a higher vapor pressure corresponds to a higher superheated temperature (e.g., the superheated vapor temperature of water is approximately 200° C. for a vapor pressure of approximately 100 pounds per square inch (psi)). As discussed above, the outlet fluid 214 is generated based on a balance of the three inputs to bring the outlet fluid 214 to a specific condition determined based on parameters measured inside the chamber 108. A temperature of the nozzle spray 212 can be determined based on a balance equation of mass and heat.

Heat can be added to the nozzle spray 212 from two different sources. In particular, heat can be added by introducing additional superheated vapor and/or by introducing additional hot liquid. By utilizing two sources of heat, the amount of superheated vapor added to the nozzle spray 212 can be modulated based on a target condition for the fluid stream 210. In particular, an amount of superheated vapor to add to the fluid stream 210 at a nozzle outlet 214 determines how wide and how much speed the fluid stream 210 exhibits. Based on calculated conditions for the fluid stream 210, additional heat can be added or compensated using the hot liquid.

In some examples, the nozzle spray 212 includes liquid (e.g., hot liquid and/or cold liquid) and gas (e.g., superheated vapor). In some examples, the nozzle spray 212 only includes gas (e.g., superheated vapor) (e.g., when the first and second valves are closed). In such examples, the nozzle 104 is to dispense the superheated vapor into the chamber 108 without the atomized spray when the first and second valves are closed. In some examples, the nozzle spray 212 includes only liquid (e.g., the hot liquid and/or the cold liquid).

In some examples, the nozzle outlet 214 is relatively large due to friction resulting from the flow of the superheated vapor. For example, the nozzle outlet 214 for the superheated vapor may be larger than a nozzle outlet for an ideal gas (e.g., air) for the same fluid flow due to superheated vapor including a larger amount of particles. In particular, the nozzle outlet 214 is sized to achieve a particular pressure and flow of the superheated vapor for the given application.

The nozzle 104 includes a liquid conduit 216 through which the hot liquid and/or the cold liquid flows. In some examples, the hot liquid and the cold liquid are mixed together in the liquid conduit 216 (e.g., internal to the nozzle 104). In some examples, the hot liquid and the cold liquid are first mixed together external to (e.g., prior to entering) the nozzle 104.

The nozzle 104 includes an example gas conduit 218 through which the superheated vapor flows through the nozzle. In this example, the liquid conduit 216 and the gas conduit 218 are separate throughout the nozzle 104. In particular, mixing of the liquid and the gas occurs external to a main body of the nozzle 104 (though the liquid and gas may be combined in the region of the nozzle outlet 214). Liquid exiting the liquid outlet 206 is met by the superheated vapor exiting the gas outlet 218. In some examples, the mixing of the liquid and the superheated vapor can occur within to the nozzle 104.

The particular construction of the nozzle 104 shown in FIG. 2 is provided for purposes of explanation. Any other suitable pneumatic (e.g., atomizing) nozzle capable of atomizing a stream of liquid (e.g., water) using a pressurized gas (e.g., superheated vapor).

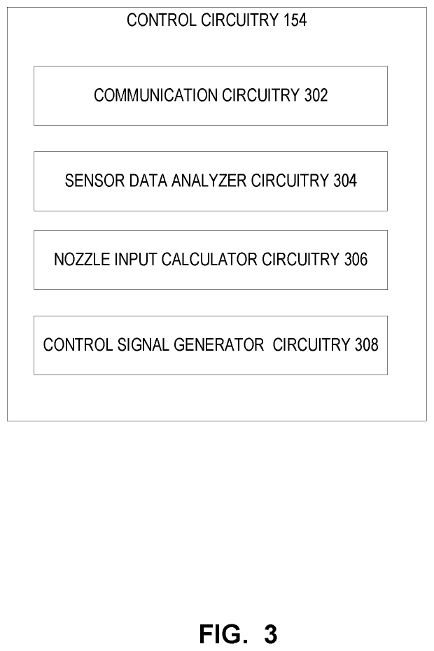

FIG. 3 is a block diagram of an example implementation of the control circuitry 154 of FIG. 1 to operate, control, and/or communicate with the various devices and control operation of the thermal control system 102. The control circuitry 154 of FIG. 3 may be instantiated (e.g., creating an instance of, bring into being for any length of time, materialize, implement, etc.) by programmable circuitry such as a Central Processor Unit (CPU) executing first instructions. Additionally or alternatively, the control circuitry 154 of FIG. 3 may be instantiated (e.g., creating an instance of, bring into being for any length of time, materialize, implement, etc.) by (i) an Application Specific Integrated Circuit (ASIC) and/or (ii) a Field Programmable Gate Array (FPGA) structured and/or configured in response to execution of second instructions to perform operations corresponding to the first instructions. It should be understood that some or all of the circuitry of FIG. 3 may, thus, be instantiated at the same or different times. Some or all of the circuitry of FIG. 3 may be instantiated, for example, in one or more threads executing concurrently on hardware and/or in series on hardware. Moreover, in some examples, some or all of the circuitry of FIG. 3 may be implemented by microprocessor circuitry executing instructions and/or FPGA circuitry performing operations to implement one or more virtual machines and/or containers.

The control circuitry 154 includes example communication circuitry 302, which enables communication with the various devices and control operation of the thermal control system 102. For example, the communication circuitry 302 can communicate with the valve(s) 118, 124, 130, 136, one or more of the sensor(s) 146-152, and/or any other device that controls and/or monitors various parameters of the thermal control system 102. In some examples, the communication circuitry 302 is instantiated by programmable circuitry executing communication instructions and/or configured to perform operations such as those represented by the flowchart(s) of FIG. 3

In some examples, the communication circuitry 302 communicates with the one or more sensors 146-152 during execution of a test to obtain and/or monitor feedback from the sensors 146-152. For example, the communication circuitry 302 can obtain an input signal (e.g., an electronic signal, etc.) from the one or more sensors 146-152 indicative of an operating condition (e.g., temperature, pressure, etc.) of a respective component of the thermal control system 102. The communication circuitry 302 can obtain one or more of the signals continuously, periodically, and/or aperiodically. The communication circuitry 302 can cause storage of the input signals in memory as sensor data from the one or more sensors 146-152.

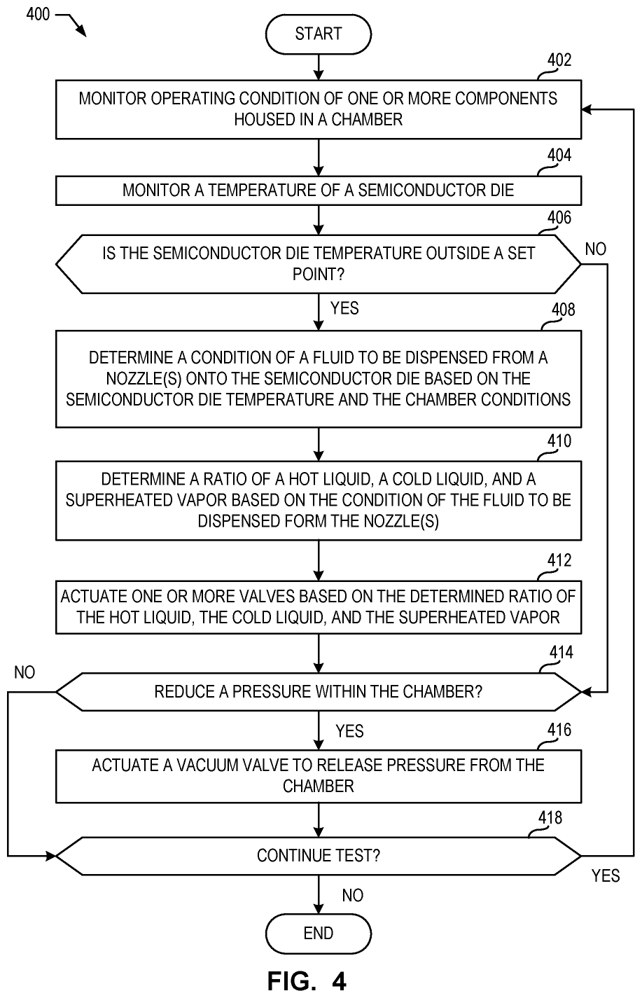

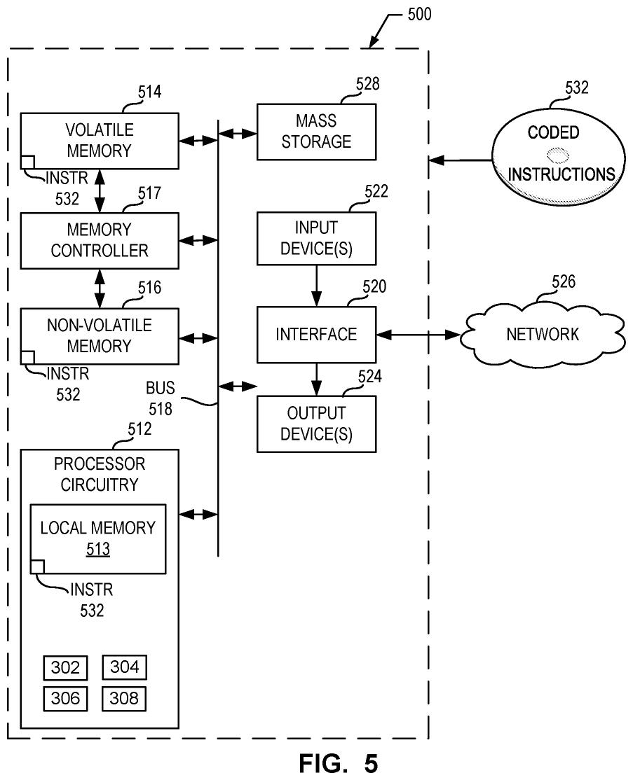

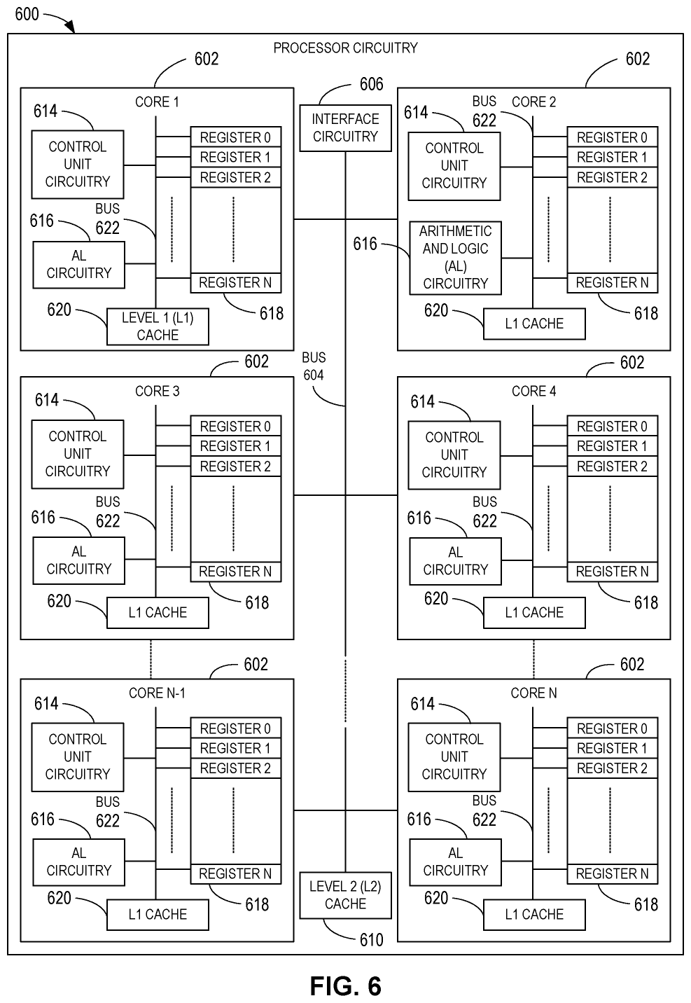

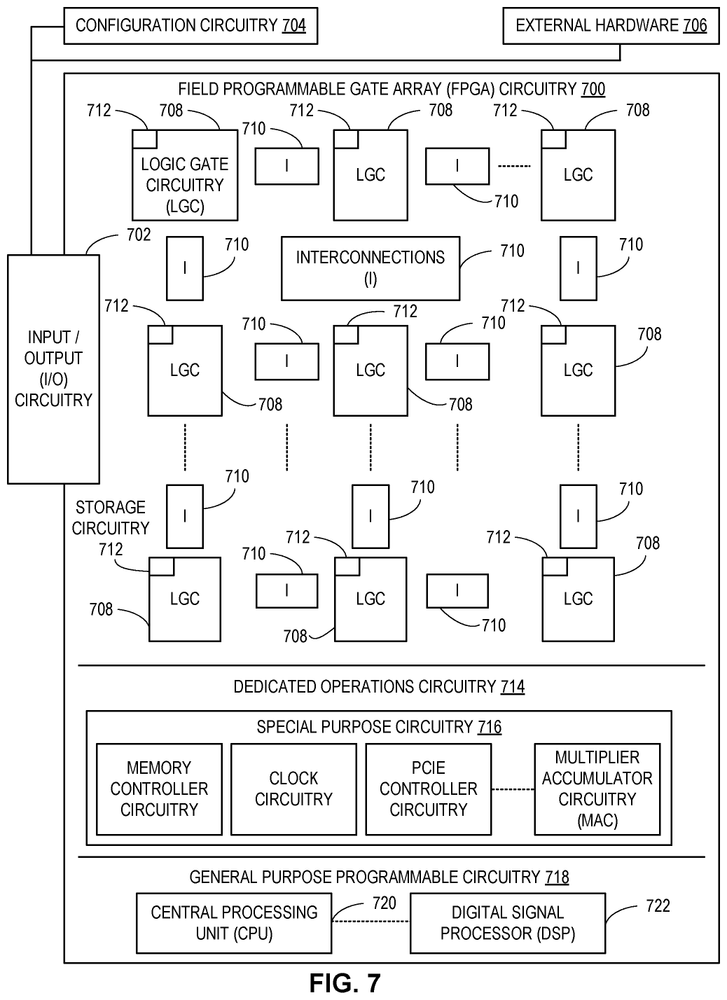

In some examples, the control circuitry 154 includes means for communicating. For example, the means for communicating may be implemented by the example communication circuitry 302. In some examples, the communication circuitry 302 may be instantiated by programmable circuitry such as the example programmable circuitry 512 of FIG. 5. For instance, the communication circuitry 302 may be instantiated by the example microprocessor 600 of FIG. 6 executing machine executable instructions such as those implemented by at least blocks 402, 404 of FIG. 4. In some examples, the communication circuitry 302 may be instantiated by hardware logic circuitry, which may be implemented by an ASIC, XPU, or the FPGA circuitry 700 of FIG. 7 configured and/or structured to perform operations corresponding to the machine readable instructions. Additionally or alternatively, the communication circuitry 302 may be instantiated by any other combination of hardware, software, and/or firmware. For example, the communication circuitry 302 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

The control circuitry 154 includes example sensor data analyzer circuitry 304, which monitors and/or analyzes sensor data from the one or more of the sensor(s) 146-152 of the thermal control system 102. In some examples, the sensor data analyzer circuitry 304 is instantiated by programmable circuitry executing sensor data analyzer instructions and/or configured to perform operations such as those represented by the flowchart(s) of FIG. 3

The sensor data analyzer circuitry 304 obtains and analyzes the signals (e.g., the sensor data) from the one or more sensors 146-152 obtained by the communication circuitry 302. For example, the sensor data analyzer circuitry 304 determines (e.g., monitors, calculates) an operating condition of one or more components housed in the chamber 108 based on the sensor data. In some examples, the sensor data analyzer circuitry 304 determines an operational pressure within the chamber 108 based on sensor data from the chamber pressure sensor 146. In some examples, the sensor data analyzer circuitry 304 determines (e.g., calculates) a saturation temperature in the chamber 108 based on the measured pressure within the chamber 108. In some examples, the sensor data analyzer circuitry 304 determines whether to the reduce a pressure within the chamber 108 based on the operational pressure within the chamber 108 provided by the chamber pressure sensor 146.

In some examples, the sensor data analyzer circuitry 304 determines a pressure of a fluid flowing through or otherwise housed in a first liquid conduit 114, a second liquid conduit 120, and/or a first gas conduit 126 based on sensor data from one or more pressure sensors 150 coupled to respective ones of the conduits 114, 120, 126. In some examples, the sensor data analyzer circuitry 304 determines a temperature of a fluid flowing through or otherwise housed in the first liquid conduit 114, the second liquid conduit 120, and/or the first gas conduit 126 based on sensor data temperature sensor 152.

In some examples, the sensor data analyzer circuitry 304 determines a temperature of the semiconductor dies 110, 112 and/or the ambient temperature within the chamber 108 based on sensor data from a temperature sensors(s) are disposed within the chamber 108. In some examples, the sensor data analyzer circuitry 304 monitors the temperature of the semiconductor dies 110, 112 to determine whether to temperature of the semiconductor dies 110, 112 is/are at (or as close as possible) to a set point (e.g., target) temperature. In some examples, the sensor data analyzer circuitry 304 monitors and/or analyzes the sensor data over time to detect or determine a rate of change and/or a direction (e.g., trend) of any changes in the sensor data and corresponding conditions indicated by the sensor data. When the semiconductor dies 110, 112 is/are outside the set point temperature, the sensor data analyzer circuitry 304 determines a fluid condition (e.g., temperature and/or pressure) of fluid to be dispensed onto the semiconductor dies 110, 112 by the nozzles 104 based on the measured conditions inside the chamber 108.

In some examples, the control circuitry 154 includes means for analyzing. For example, the means for analyzing may be implemented by the example sensor data analyzer circuitry 304. In some examples, the sensor data analyzer circuitry 304 may be instantiated by programmable circuitry such as the example programmable circuitry 512 of FIG. 5. For instance, the sensor data analyzer circuitry 304 may be instantiated by the example microprocessor 600 of FIG. 6 executing machine executable instructions such as those implemented by at least blocks 402-408, 414 of FIG. 4. In some examples, the sensor data analyzer circuitry 304 may be instantiated by hardware logic circuitry, which may be implemented by an ASIC, XPU, or the FPGA circuitry 700 of FIG. 7 configured and/or structured to perform operations corresponding to the machine readable instructions. Additionally or alternatively, the sensor data analyzer circuitry 304 may be instantiated by any other combination of hardware, software, and/or firmware. For example, the sensor data analyzer circuitry 304 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

The control circuitry 154 includes example nozzle input calculator circuitry 306, which determines a ratio of a hot liquid (e.g., hot water), a cold liquid (e.g., cold water), and/or a superheated vapor to be provided to and dispensed by the nozzles 104. The ratio defines proportions of the first liquid, the second liquid, and the superheated vapor to be provided to the pneumatic nozzle. In particular, the nozzle input calculate circuitry 306 determines the ratio of the hot liquid, the cold liquid, and/or the superheated vapor based on the condition of the fluid to be dispensed by the nozzles 104 as determined by the sensor data analyzer circuitry 304. Additionally or alternatively, in some examples, the nozzle input calculate circuitry 306 determines the ratio based on a mass and energy balance equation. In some examples, the nozzle input calculator circuitry 306 is instantiated by programmable circuitry executing nozzle input calculator instructions and/or configured to perform operations such as those represented by the flowchart(s) of FIG. 3.

As discussed above, each nozzle 104 includes three inputs: the superheated vapor, the hot liquid, and the cold liquid. The nozzle input calculator circuitry 306 determines a mass and energy balance that will meet operational requirements by controlling the ratio of hot liquid, the cold liquid, and the superheated vapor to the nozzles 104. The hot liquid and the cold liquid can be combined to generate a combined liquid at a given temperature. The superheated vapor adds kinetic energy and heat, which will be transferred to the combined liquid. The three inputs can be balanced such that the nozzles 104 output a fluid having a specific temperature and a specific speed.

In some examples, the control circuitry 154 includes means for calculating. For example, the means for calculating may be implemented by the example communication circuitry 302. In some examples, the example nozzle input calculator circuitry 306 may be instantiated by programmable circuitry such as the example programmable circuitry 512 of FIG. 5. For instance, the nozzle input calculator circuitry 306 may be instantiated by the example microprocessor 600 of FIG. 6 executing machine executable instructions such as those implemented by at least blocks 410 of FIG. 4. In some examples, the nozzle input calculator circuitry 306 may be instantiated by hardware logic circuitry, which may be implemented by an ASIC, XPU, or the FPGA circuitry 700 of FIG. 7 configured and/or structured to perform operations corresponding to the machine readable instructions. Additionally or alternatively, the nozzle input calculator circuitry 306 may be instantiated by any other combination of hardware, software, and/or firmware. For example, the nozzle input calculator circuitry 306 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

The control circuitry 154 includes example control signal generator circuitry 308, which generates control signals to send to one or more of the valves 118, 124, 130, 136 based on the ratio of fluids determined by the nozzle input calculator circuitry 306 and/or based on the conditions in the chamber 108 determined by the sensor data analyzer circuitry 304. In some examples, the control signal generator circuitry 308 is instantiated by programmable circuitry executing control signal generator instructions and/or configured to perform operations such as those represented by the flowchart(s) of FIG. 3.

In operation, the control signal generator circuitry 308 generates and sends an output signal (e.g., control signal, etc.) to ones of the valves 118, 124, 130, 136 (or associated actuators operatively coupled to the valves) to actuate the valves to move a core (e.g., plunger, disk, diaphragm, ball, globe, gate, etc.) of the valves 118, 124, 130, 136 to a position indicated by the output signal (e.g., to an opened position, a closed position, or a partially opened position). In some examples, the control signal generator circuitry 308 causes one or more of the valves 118, 124, 130 to completely closes to block (e.g., cut-off) one or more of the hot liquid, the cold liquid, or the superheated vapor from entering the chamber 108. In some examples, the control signal generator circuitry 308 causes one or more of the valves 118, 124, 130 to move to a set position based on a ratio of the hot liquid, the cold liquid, and/or the superheated vapor to be dispensed by the nozzles 104. In some examples, the control signal generator circuitry 308 causes the fourth valves 136 to open to release pressure from the chamber 108.

In some examples, the control circuitry 154 includes means for generating a control signal(s). For example, the means for generating a control signal(s) may be implemented by the example control signal generator circuitry 308. In some examples, the control signal generator circuitry 308 may be instantiated by programmable circuitry such as the example programmable circuitry 512 of FIG. 5. For instance, the control signal generator circuitry 308 may be instantiated by the example microprocessor 600 of FIG. 6 executing machine executable instructions such as those implemented by at least blocks 412, 416 of FIG. 4. In some examples, the control signal generator circuitry 308 may be instantiated by hardware logic circuitry, which may be implemented by an ASIC, XPU, or the FPGA circuitry 700 of FIG. 7 configured and/or structured to perform operations corresponding to the machine readable instructions. Additionally or alternatively, the control signal generator circuitry 308 may be instantiated by any other combination of hardware, software, and/or firmware. For example, the control signal generator circuitry 308 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

While an example manner of implementing the control circuitry 154 of FIG. 1 is illustrated in FIG. 3, one or more of the elements, processes, and/or devices illustrated in FIG. 3 may be combined, divided, re-arranged, omitted, eliminated, and/or implemented in any other way. Further, the example communication circuitry 302, example sensor data analyzer circuitry 304, example nozzle input calculator circuitry 306, example control signal generator circuitry 308, and/or, more generally, the example control circuitry 154 of FIG. 3, may be implemented by hardware alone or by hardware in combination with software and/or firmware. Thus, for example, any of the example communication circuitry 302, example sensor data analyzer circuitry 304, example nozzle input calculator circuitry 306, example control signal generator circuitry 308 and/or, more generally, the example control circuitry 154, could be implemented by programmable circuitry in combination with machine readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), and/or field programmable logic device(s) (FPLD(s)) such as FPGAs. Further still, the example control circuitry 154 of FIG. 3 may include one or more elements, processes, and/or devices in addition to, or instead of, those illustrated in FIG. 3, and/or may include more than one of any or all of the illustrated elements, processes and devices.

A flowchart representative of example machine readable instructions, which may be executed by programmable circuitry to implement and/or instantiate the control circuitry 154 of FIG. 3 and/or representative of example operations which may be performed by programmable circuitry to implement and/or instantiate the control circuitry 154 of FIG. 3, is shown in FIG. 4. The machine readable instructions may be one or more executable programs or portion(s) of one or more executable programs for execution by programmable circuitry such as the programmable circuitry 512 shown in the example processor platform 500 discussed below in connection with FIG. 5 and/or may be one or more function(s) or portion(s) of functions to be performed by the example programmable circuitry (e.g., an FPGA) discussed below in connection with FIGS. 6 and/or 7. In some examples, the machine readable instructions cause an operation, a task, etc., to be carried out and/or performed in an automated manner in the real world. As used herein, “automated” means without human involvement.

The program may be embodied in instructions (e.g., software and/or firmware) stored on one or more non-transitory computer readable and/or machine readable storage medium such as cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), and/or any other storage device or storage disk. The instructions of the non-transitory computer readable and/or machine readable medium may program and/or be executed by programmable circuitry located in one or more hardware devices, but the entire program and/or parts thereof could alternatively be executed and/or instantiated by one or more hardware devices other than the programmable circuitry and/or embodied in dedicated hardware. The machine readable instructions may be distributed across multiple hardware devices and/or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart(s) illustrated in FIG. 4, many other methods of implementing the example control circuitry 154 may alternatively be used. For example, the order of execution of the blocks of the flowchart(s) may be changed, and/or some of the blocks described may be changed, eliminated, or combined. Additionally or alternatively, any or all of the blocks of the flow chart may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations and/or local to one or more hardware devices (e.g., a single-core processor (e.g., a single core CPU), a multi-core processor (e.g., a multi-core CPU, an XPU, etc.)). For example, the programmable circuitry may be a CPU and/or an FPGA located in the same package (e.g., the same integrated circuit (IC) package or in two or more separate housings), one or more processors in a single machine, multiple processors distributed across multiple servers of a server rack, multiple processors distributed across one or more server racks, etc., and/or any combination(s) thereof.

The machine readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, and/or produce machine executable instructions. For example, the machine readable instructions may be fragmented and stored on one or more storage devices, disks and/or computing devices (e.g., servers) located at the same or different locations of a network or collection of networks (e.g., in the cloud, in edge devices, etc.). The machine readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine readable instructions may be stored in multiple parts, which are individually compressed, encrypted, and/or stored on separate computing devices, wherein the parts when decrypted, decompressed, and/or combined form a set of computer-executable and/or machine executable instructions that implement one or more functions and/or operations that may together form a program such as that described herein.

In another example, the machine readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine readable instructions may need to be configured (e.g., settings stored, data input, network addresses recorded, etc.) before the machine readable instructions and/or the corresponding program(s) can be executed in whole or in part. Thus, machine readable, computer readable and/or machine readable media, as used herein, may include instructions and/or program(s) regardless of the particular format or state of the machine readable instructions and/or program(s).

The machine readable instructions described herein can be represented by any past, present, or future instruction language, scripting language, programming language, etc. For example, the machine readable instructions may be represented using any of the following languages: C, C++, Java, C#, Perl, Python, JavaScript, HyperText Markup Language (HTML), Structured Query Language (SQL), Swift, etc.

As mentioned above, the example operations of FIG. 4 may be implemented using executable instructions (e.g., computer readable and/or machine readable instructions) stored on one or more non-transitory computer readable and/or machine readable media. As used herein, the terms non-transitory computer readable medium, non-transitory computer readable storage medium, non-transitory machine readable medium, and/or non-transitory machine readable storage medium are expressly defined to include any type of computer readable storage device and/or storage disk and to exclude propagating signals and to exclude transmission media. Examples of such non-transitory computer readable medium, non-transitory computer readable storage medium, non-transitory machine readable medium, and/or non-transitory machine readable storage medium include optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms “non-transitory computer readable storage device” and “non-transitory machine readable storage device” are defined to include any physical (mechanical, magnetic and/or electrical) hardware to retain information for a time period, but to exclude propagating signals and to exclude transmission media. Examples of non-transitory computer readable storage devices and/or non-transitory machine readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer readable instructions, machine readable instructions, etc., and/or manufactured to execute computer-readable instructions, machine-readable instructions, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

FIG. 4 is a flowchart representative of example machine readable instructions and/or example operations 400 that may be executed, instantiated, and/or performed by programmable circuitry to execute a thermal test for an IC package (e.g., the IC package 105 containing the semiconductor die 110, 112). The example machine-readable instructions and/or the example operations 400 of FIG. 4 begin at block 402, at which the control circuitry 154 monitors an operating condition(s) of one or more components housed in a chamber 108. For example, the example sensor data analyzer circuitry 304 determines operating parameters of one or more components of a thermal control system 102 based on sensor data from one or more sensors 146-152. In some examples, the control circuitry 154 obtains (via the communication circuitry 302) a chamber pressure measurement from the chamber pressure sensor 146, fluid pressure measurements from the pressure sensors 150 coupled to each of the first liquid conduit 114, the second liquid conduit 120, and the first gas conduit 126, and fluid temperature measurements from the temperature sensors 152 coupled to each of the first liquid conduit 114, the second liquid conduit 120, and the first gas conduit 126.

At block 404, the control circuitry 154 monitors a temperature of a semiconductor die 110, 112 being tested. For example, the example sensor data analyzer circuitry 304 monitors a die temperature measurements from a temperature sensor 148 disposed within the chamber 108 and positioned to measure the temperature of the semiconductor dies 110, 112 based on sensor data obtained via the communication circuitry 302.

At block 406, the control circuitry 154 whether the semiconductor die temperature(s) is outside a set point. In particular, the example sensor data analyzer circuitry 304 determines whether the die temperature of the semiconductor die 110, 112 is at (or as close as possible) to a target (e.g., a set point) temperature for the semiconductor die 110, 112 and/or has/is deviating away from the target temperature. In some examples, the semiconductor die temperature(s) may be outside the set point when a difference between measured temperature and the target temperature is less than a threshold. In some examples, the semiconductor die temperature(s) may be outside the set point whenever the temperature exceeds the set point (for a high set point) falls below the set point (for a low set point). When the answer to block 406 is NO, control advances to block 414. When the answer to block 406 is YES, control advances to block 408.

At block 408, the control circuitry 154 determines a condition of a fluid to be dispensed from a nozzle(s) onto the semiconductor die based on the semiconductor die temperature and the chamber conditions. For example, the example sensor data analyzer circuitry 304 determines a temperature, a pressure, and/or a speed of the fluid to be dispensed onto the semiconductor die 110, 112 by the nozzles 104 based on the die temperature of the semiconductor die 110, 112 and/or the conditions (e.g., temperature, pressure, etc.) of the one or more components housed in the chamber 108.

At block 410, the control circuitry 154 determines a ratio of a hot liquid, a cold liquid, and a superheated vapor based on the condition of the fluid to be dispensed from the nozzle(s) 104. In particular, the nozzle 104 includes three inputs: superheated vapor, hot liquid, and cold liquid. Thus, based on the determined condition of the fluid to be dispensed by the nozzle 104, the example nozzle input calculator circuitry 306 determines a ratio of the hot liquid, the cold liquid, and the superheated vapor to meet operational requirements. In some examples, the determination is based on a balance of mass and energy. The three inputs can be balanced such that the nozzles 104 output the fluid having the determined condition in the chamber 108.

At block 412, the control circuitry 154 actuates one or more valve 118, 124, 130 based on the determined ratio of the hot liquid, the cold liquid, and the superheated vapor. In particular, the control circuitry 154 controls and/or causes actuation of movement of a core of one or more of valves 118, 124, 130 to an opened position, a closed position, or a partially opened position based on the determined ratio. For example, the example control signal generator circuitry 308 can generate and send (via the communication circuitry 302) a control signal to the one or more valve 118, 124, 130 to cause the valve 118, 124, 130 to move to an opened position, a closed position, or a partially opened position.

At block 414, the control circuitry 154 determines whether to reduce a pressure within the chamber. In some examples, this determination is made by the example sensor data analyzer circuitry 302 based on an analysis of the measured conditions inside the chamber 108. When the answer to block 410 is YES, control advances to block 416 at which the control circuitry 154 actuates a vacuum valve to release pressure from the chamber. In particular, the vacuum valve can be opened by a control signal generated by the control signal generator circuitry 308 to allow fluid flow through a chamber outlet 134 of the chamber 108 to reduce a pressure within the chamber 108. When the answer to block 414 is NO, control advances to block 418.

At block 418, the control circuitry 154 determines whether to continue the test. When the answer to block 418 is YES, control returns to block 402. The control circuitry 154 proceeds to iterate through blocks 402-416. In particular, the control circuitry 154 iterates through blocks 402-416 until the answer to block 418 is NO.

FIG. 5 is a block diagram of an example programmable circuitry platform 500 structured to execute and/or instantiate the example machine-readable instructions and/or the example operations of FIG. 4 to implement the control circuitry 154 of FIG. 3. The programmable circuitry platform 500 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a Blu-ray player, a gaming console, a personal video recorder, a set top box, a headset (e.g., an augmented reality (AR) headset, a virtual reality (VR) headset, etc.) or other wearable device, or any other type of computing and/or electronic device.

The programmable circuitry platform 500 of the illustrated example includes programmable circuitry 512. The programmable circuitry 512 of the illustrated example is hardware. For example, the programmable circuitry 512 can be implemented by one or more integrated circuits, logic circuits, FPGAs, microprocessors, CPUs, GPUs, DSPs, and/or microcontrollers from any desired family or manufacturer. The programmable circuitry 512 may be implemented by one or more semiconductor based (e.g., silicon based) devices. In this example, the programmable circuitry 512 implements example communication circuitry 302, example sensor data analyzer circuitry 304, example nozzle input calculator circuitry 306, and example control signal generator circuitry 308.

The programmable circuitry 512 of the illustrated example includes a local memory 513 (e.g., a cache, registers, etc.). The programmable circuitry 512 of the illustrated example is in communication with main memory 514, 516, which includes a volatile memory 514 and a non-volatile memory 516, by a bus 518. The volatile memory 514 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 516 may be implemented by flash memory and/or any other desired type of memory device. Access to the main memory 514, 516 of the illustrated example is controlled by a memory controller 517. In some examples, the memory controller 517 may be implemented by one or more integrated circuits, logic circuits, microcontrollers from any desired family or manufacturer, or any other type of circuitry to manage the flow of data going to and from the main memory 514, 516.

The programmable circuitry platform 500 of the illustrated example also includes interface circuitry 520. The interface circuitry 520 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 522 are connected to the interface circuitry 520. The input device(s) 522 permit(s) a user (e.g., a human user, a machine user, etc.) to enter data and/or commands into the programmable circuitry 512. The input device(s) 522 can be implemented by, for example, one or more sensors (e.g., pressure sensor(s), temperature sensor(s), etc., an audio sensor, a microphone, a camera (still or video), a keyboard, a button, a mouse, a touchscreen, a trackpad, a trackball, an isopoint device, and/or a voice recognition system.

One or more output devices 524 are also connected to the interface circuitry 520 of the illustrated example. The output device(s) 524 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 520 of the illustrated example, thus, typically includes a graphics driver card, a graphics driver chip, and/or graphics processor circuitry such as a GPU.

The interface circuitry 520 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 526. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 500 of the illustrated example also includes one or more mass storage discs or devices 528 to store firmware, software, and/or data. Examples of such mass storage discs or devices 528 include magnetic storage devices (e.g., floppy disk, drives, HDDs, etc.), optical storage devices (e.g., Blu-ray disks, CDs, DVDs, etc.), RAID systems, and/or solid-state storage discs or devices such as flash memory devices and/or SSDs.

The machine readable instructions 532, which may be implemented by the machine readable instructions of FIG. 4, may be stored in the mass storage device 528, in the volatile memory 514, in the non-volatile memory 516, and/or on at least one non-transitory computer readable storage medium such as a CD or DVD which may be removable.

FIG. 6 is a block diagram of an example implementation of the programmable circuitry 512 of FIG. 5. In this example, the programmable circuitry 512 of FIG. 5 is implemented by a microprocessor 600. For example, the microprocessor 600 may be a general-purpose microprocessor (e.g., general-purpose microprocessor circuitry). The microprocessor 600 executes some or all of the machine-readable instructions of the flowchart(s) of FIG. 4 to effectively instantiate the circuitry of FIG. 3 as logic circuits to perform operations corresponding to those machine readable instructions. In some such examples, the circuitry of FIG. 3 is instantiated by the hardware circuits of the microprocessor 600 in combination with the machine-readable instructions. For example, the microprocessor 600 may be implemented by multi-core hardware circuitry such as a CPU, a DSP, a GPU, an XPU, etc. Although it may include any number of example cores 602 (e.g., 1 core), the microprocessor 600 of this example is a multi-core semiconductor device including N cores. The cores 602 of the microprocessor 600 may operate independently or may cooperate to execute machine readable instructions. For example, machine code corresponding to a firmware program, an embedded software program, or a software program may be executed by one of the cores 602 or may be executed by multiple ones of the cores 602 at the same or different times. In some examples, the machine code corresponding to the firmware program, the embedded software program, or the software program is split into threads and executed in parallel by two or more of the cores 602. The software program may correspond to a portion or all of the machine readable instructions and/or operations represented by the flowchart(s) of FIG. 4.

The cores 602 may communicate by a first example bus 604. In some examples, the first bus 604 may be implemented by a communication bus to effectuate communication associated with one(s) of the cores 602. For example, the first bus 604 may be implemented by at least one of an Inter-Integrated Circuit (I2C) bus, a Serial Peripheral Interface (SPI) bus, a PCI bus, or a PCIe bus. Additionally or alternatively, the first bus 604 may be implemented by any other type of computing or electrical bus. The cores 602 may obtain data, instructions, and/or signals from one or more external devices by example interface circuitry 606. The cores 602 may output data, instructions, and/or signals to the one or more external devices by the interface circuitry 606. Although the cores 602 of this example include example local memory 620 (e.g., Level 1 (L1) cache that may be split into an L1 data cache and an L1 instruction cache), the microprocessor 600 also includes example shared memory 610 that may be shared by the cores (e.g., Level 2 (L2 cache)) for high-speed access to data and/or instructions. Data and/or instructions may be transferred (e.g., shared) by writing to and/or reading from the shared memory 610. The local memory 620 of each of the cores 602 and the shared memory 610 may be part of a hierarchy of storage devices including multiple levels of cache memory and the main memory (e.g., the main memory 514, 516 of FIG. 5). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 602 may be referred to as a CPU, DSP, GPU, etc., or any other type of hardware circuitry. Each core 602 includes control unit circuitry 614, arithmetic and logic (AL) circuitry (sometimes referred to as an ALU) 616, a plurality of registers 618, the local memory 620, and a second example bus 622. Other structures may be present. For example, each core 602 may include vector unit circuitry, single instruction multiple data (SIMD) unit circuitry, load/store unit (LSU) circuitry, branch/jump unit circuitry, floating-point unit (FPU) circuitry, etc. The control unit circuitry 614 includes semiconductor-based circuits structured to control (e.g., coordinate) data movement within the corresponding core 602. The AL circuitry 616 includes semiconductor-based circuits structured to perform one or more mathematic and/or logic operations on the data within the corresponding core 602. The AL circuitry 616 of some examples performs integer based operations. In other examples, the AL circuitry 616 also performs floating-point operations. In yet other examples, the AL circuitry 616 may include first AL circuitry that performs integer-based operations and second AL circuitry that performs floating-point operations. In some examples, the AL circuitry 616 may be referred to as an Arithmetic Logic Unit (ALU).

The registers 618 are semiconductor-based structures to store data and/or instructions such as results of one or more of the operations performed by the AL circuitry 616 of the corresponding core 602. For example, the registers 618 may include vector register(s), SIMD register(s), general-purpose register(s), flag register(s), segment register(s), machine-specific register(s), instruction pointer register(s), control register(s), debug register(s), memory management register(s), machine check register(s), etc. The registers 618 may be arranged in a bank as shown in FIG. 6.

Alternatively, the registers 618 may be organized in any other arrangement, format, or structure, such as by being distributed throughout the core 602 to shorten access time. The second bus 622 may be implemented by at least one of an I2C bus, a SPI bus, a PCI bus, or a PCIe bus.

Each core 602 and/or, more generally, the microprocessor 600 may include additional and/or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. The microprocessor 600 is a semiconductor device fabricated to include many transistors interconnected to implement the structures described above in one or more integrated circuits (ICs) contained in one or more packages.

The microprocessor 600 may include and/or cooperate with one or more accelerators (e.g., acceleration circuitry, hardware accelerators, etc.). In some examples, accelerators are implemented by logic circuitry to perform certain tasks more quickly and/or efficiently than can be done by a general-purpose processor. Examples of accelerators include ASICs and FPGAs such as those discussed herein. A GPU, DSP and/or other programmable device can also be an accelerator. Accelerators may be on-board the microprocessor 600, in the same chip package as the microprocessor 600 and/or in one or more separate packages from the microprocessor 600.

FIG. 7 is a block diagram of another example implementation of the programmable circuitry 512 of FIG. 5. In this example, the programmable circuitry 512 is implemented by FPGA circuitry 700. For example, the FPGA circuitry 700 may be implemented by an FPGA. The FPGA circuitry 700 can be used, for example, to perform operations that could otherwise be performed by the example microprocessor 600 of FIG. 6 executing corresponding machine readable instructions. However, once configured, the FPGA circuitry 700 instantiates the operations and/or functions corresponding to the machine readable instructions in hardware and, thus, can often execute the operations/functions faster than they could be performed by a general-purpose microprocessor executing the corresponding software.

More specifically, in contrast to the microprocessor 600 of FIG. 6 described above (which is a general purpose device that may be programmed to execute some or all of the machine readable instructions represented by the flowchart(s) of FIG. 4 but whose interconnections and logic circuitry are fixed once fabricated), the FPGA circuitry 700 of the example of FIG. 7 includes interconnections and logic circuitry that may be configured, structured, programmed, and/or interconnected in different ways after fabrication to instantiate, for example, some or all of the operations/functions corresponding to the machine readable instructions represented by the flowchart(s) of FIG. 4. In particular, the FPGA circuitry 700 may be thought of as an array of logic gates, interconnections, and switches. The switches can be programmed to change how the logic gates are interconnected by the interconnections, effectively forming one or more dedicated logic circuits (unless and until the FPGA circuitry 700 is reprogrammed). The configured logic circuits enable the logic gates to cooperate in different ways to perform different operations on data received by input circuitry. Those operations may correspond to some or all of the instructions (e.g., the software and/or firmware) represented by the flowchart(s) of FIG. 4. As such, the FPGA circuitry 700 may be configured and/or structured to effectively instantiate some or all of the operations/functions corresponding to the machine readable instructions of the flowchart(s) of FIG. 4 as dedicated logic circuits to perform the operations/functions corresponding to those software instructions in a dedicated manner analogous to an ASIC. Therefore, the FPGA circuitry 700 may perform the operations/functions corresponding to the some or all of the machine readable instructions of FIG. 4 faster than the general-purpose microprocessor can execute the same.

In the example of FIG. 7, the FPGA circuitry 700 is configured and/or structured in response to being programmed (and/or reprogrammed one or more times) based on a binary file. In some examples, the binary file may be compiled and/or generated based on instructions in a hardware description language (HDL) such as Lucid, Very High Speed Integrated Circuits (VHSIC) Hardware Description Language (VHDL), or Verilog. For example, a user (e.g., a human user, a machine user, etc.) may write code or a program corresponding to one or more operations/functions in an HDL; the code/program may be translated into a low-level language as needed; and the code/program (e.g., the code/program in the low-level language) may be converted (e.g., by a compiler, a software application, etc.) into the binary file. In some examples, the FPGA circuitry 700 of FIG. 7 may access and/or load the binary file to cause the FPGA circuitry 700 of FIG. 7 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 700 of FIG. 7 to cause configuration and/or structuring of the FPGA circuitry 700 of FIG. 7, or portion(s) thereof.

In some examples, the binary file is compiled, generated, transformed, and/or otherwise output from a uniform software platform utilized to program FPGAs. For example, the uniform software platform may translate first instructions (e.g., code or a program) that correspond to one or more operations/functions in a high-level language (e.g., C, C++, Python, etc.) into second instructions that correspond to the one or more operations/functions in an HDL. In some such examples, the binary file is compiled, generated, and/or otherwise output from the uniform software platform based on the second instructions. In some examples, the FPGA circuitry 700 of FIG. 7 may access and/or load the binary file to cause the FPGA circuitry 700 of FIG. 7 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 700 of FIG. 7 to cause configuration and/or structuring of the FPGA circuitry 700 of FIG. 7, or portion(s) thereof.

The FPGA circuitry 700 of FIG. 7, includes example input/output (I/O) circuitry 702 to obtain and/or output data to/from example configuration circuitry 704 and/or external hardware 706. For example, the configuration circuitry 704 may be implemented by interface circuitry that may obtain a binary file, which may be implemented by a bit stream, data, and/or machine-readable instructions, to configure the FPGA circuitry 700, or portion(s) thereof. In some such examples, the configuration circuitry 704 may obtain the binary file from a user, a machine (e.g., hardware circuitry (e.g., programmable or dedicated circuitry) that may implement an Artificial Intelligence/Machine Learning (AI/ML) model to generate the binary file), etc., and/or any combination(s) thereof). In some examples, the external hardware 706 may be implemented by external hardware circuitry. For example, the external hardware 706 may be implemented by the microprocessor 600 of FIG. 6.

The FPGA circuitry 700 also includes an array of example logic gate circuitry 708, a plurality of example configurable interconnections 710, and example storage circuitry 712. The logic gate circuitry 708 and the configurable interconnections 710 are configurable to instantiate one or more operations/functions that may correspond to at least some of the machine readable instructions of FIG. 4 and/or other desired operations. The logic gate circuitry 708 shown in FIG. 7 is fabricated in blocks or groups. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 708 to enable configuration of the electrical structures and/or the logic gates to form circuits to perform desired operations/functions. The logic gate circuitry 708 may include other electrical structures such as look-up tables (LUTs), registers (e.g., flip-flops or latches), multiplexers, etc.

The configurable interconnections 710 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 708 to program desired logic circuits.

The storage circuitry 712 of the illustrated example is structured to store result(s) of the one or more of the operations performed by corresponding logic gates. The storage circuitry 712 may be implemented by registers or the like. In the illustrated example, the storage circuitry 712 is distributed amongst the logic gate circuitry 708 to facilitate access and increase execution speed.

The example FPGA circuitry 700 of FIG. 7 also includes example dedicated operations circuitry 714. In this example, the dedicated operations circuitry 714 includes special purpose circuitry 716 that may be invoked to implement commonly used functions to avoid the need to program those functions in the field. Examples of such special purpose circuitry 716 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 700 may also include example general purpose programmable circuitry 718 such as an example CPU 720 and/or an example DSP 722. Other general purpose programmable circuitry 718 may additionally or alternatively be present such as a GPU, an XPU, etc., that can be programmed to perform other operations.

Although FIGS. 6 and 7 illustrate two example implementations of the programmable circuitry 512 of FIG. 5, many other approaches are contemplated. For example, FPGA circuitry may include an on-board CPU, such as one or more of the example CPU 720 of FIG. 6. Therefore, the programmable circuitry 512 of FIG. 5 may additionally be implemented by combining at least the example microprocessor 600 of FIG. 6 and the example FPGA circuitry 700 of FIG. 7. In some such hybrid examples, one or more cores 602 of FIG. 6 may execute a first portion of the machine readable instructions represented by the flowchart(s) of FIG. 4 to perform first operation(s)/function(s), the FPGA circuitry 700 of FIG. 7 may be configured and/or structured to perform second operation(s)/function(s) corresponding to a second portion of the machine readable instructions represented by the flowchart(s) of FIG. 4, and/or an ASIC may be configured and/or structured to perform third operation(s)/function(s) corresponding to a third portion of the machine readable instructions represented by the flowchart(s) of FIG. 4.

It should be understood that some or all of the circuitry of FIG. 3 may, thus, be instantiated at the same or different times. For example, same and/or different portion(s) of the microprocessor 600 of FIG. 6 may be programmed to execute portion(s) of machine-readable instructions at the same and/or different times. In some examples, same and/or different portion(s) of the FPGA circuitry 700 of FIG. 7 may be configured and/or structured to perform operations/functions corresponding to portion(s) of machine-readable instructions at the same and/or different times.

In some examples, some or all of the circuitry of FIG. 3 may be instantiated, for example, in one or more threads executing concurrently and/or in series. For example, the microprocessor 600 of FIG. 6 may execute machine readable instructions in one or more threads executing concurrently and/or in series. In some examples, the FPGA circuitry 700 of FIG. 7 may be configured and/or structured to carry out operations/functions concurrently and/or in series. Moreover, in some examples, some or all of the circuitry of FIG. 3 may be implemented within one or more virtual machines and/or containers executing on the microprocessor 600 of FIG. 6.

In some examples, the programmable circuitry 512 of FIG. 5 may be in one or more packages. For example, the microprocessor 600 of FIG. 6 and/or the FPGA circuitry 700 of FIG. 7 may be in one or more packages. In some examples, an XPU may be implemented by the programmable circuitry 512 of FIG. 5, which may be in one or more packages. For example, the XPU may include a CPU (e.g., the microprocessor 600 of FIG. 6, the CPU 720 of FIG. 7, etc.) in one package, a DSP (e.g., the DSP 722 of FIG. 7) in another package, a GPU in yet another package, and an FPGA (e.g., the FPGA circuitry 700 of FIG. 7) in still yet another package.

From the foregoing, it will be appreciated that example systems, apparatus, articles of manufacture, and methods have been disclosed that improve testing of integrated circuit packages. In particular, examples disclosed herein enable improved thermal control by utilizing an example nozzle structured in accordance with teachings disclosed herein.

Example methods, apparatus, systems, and articles of manufacture to improve thermal tests of integrated circuit devices are disclosed herein. Further examples and combinations thereof include the following:

Example 1 includes an apparatus comprising interface circuitry, machine readable instructions, and programmable circuitry to at least one of instantiate or execute the machine readable instructions to determine a condition of a fluid to be dispensed by a pneumatic nozzle, the condition of the fluid including a temperature of the fluid, determine a ratio of a first liquid, a second liquid, and a superheated vapor that combine to result in the condition of the fluid, and cause the first liquid, the second liquid, and the superheated vapor to be provided to the pneumatic nozzle in proportions defined by the ratio.

Example 2 includes the apparatus of example 1, wherein the programmable circuitry is to determine the condition of the fluid based on a first temperature associated with a semiconductor device and a second temperature associated with a semiconductor device, the first temperature being an operating temperature of the semiconductor device, the second temperature being a target temperature of the semiconductor device.

Example 3 includes the apparatus of example 1, wherein the programmable circuitry is to control the proportions of the first liquid, the second liquid, and the superheated vapor provided to the pneumatic nozzle by causing adjustment of at least one of a first valve associated with the first liquid, a second valve associated with the second liquid, or a third valve associated with the superheated vapor.

Example 4 includes the apparatus of example 3, wherein the programmable circuitry is to cause the first valve associated with the first liquid and the second valve associated with the second liquid to close to cut-off a liquid supply to the pneumatic nozzle.

Example 5 includes the apparatus of example 3, wherein the programmable circuitry is to determine a chamber pressure within a chamber in which the pneumatic nozzle is disposed, and cause adjustment to a fourth valve associated with a chamber outlet based on the chamber pressure within the chamber.

Example 6 includes the apparatus of example 1, wherein the first liquid having a first temperature, the second liquid having a second temperature higher than the first temperature, the superheated vapor having a third temperature higher than the second temperature.

Example 7 includes the apparatus of example 1, wherein the programmable circuitry is to determine the condition of the fluid to be dispensed by the pneumatic nozzle based on a saturation temperature of the first and second liquids in a chamber containing the pneumatic nozzle.

Example 8 includes a non-transitory machine readable storage medium comprising instructions to cause programmable circuitry to at least determine a condition of a fluid to be dispensed by a pneumatic nozzle, the condition of the fluid including a temperature of the fluid, determine a ratio of a first liquid, a second liquid, and a superheated vapor that combine to result in the condition of the fluid, and cause the first liquid, the second liquid, and the superheated vapor to be provided to the pneumatic nozzle in proportions defined by the ratio.

Example 9 includes the non-transitory machine readable storage medium of example 8, wherein the instructions are to cause the programmable circuitry to determine the condition of the fluid based on a first temperature associated with a semiconductor device and a second temperature associated with a semiconductor device, the first temperature being an operating temperature of the semiconductor device, the second temperature being a target temperature of the semiconductor device.

Example 10 includes the non-transitory machine readable storage medium of example 8, wherein the instructions are to cause the programmable circuitry to control the proportions of the first liquid, the second liquid, and the superheated vapor provided to the pneumatic nozzle by causing adjustment of at least one of a first valve associated with the first liquid, a second valve associated with the second liquid, or a third valve associated with the superheated vapor.

Example 11 includes the non-transitory machine readable storage medium of example 10, wherein the instructions are to cause the programmable circuitry to cause the first valve associated with the first liquid and the second valve associated with the second liquid to close to cut-off a liquid supply to the pneumatic nozzle.

Example 12 includes the non-transitory machine readable storage medium of example 10, wherein the instructions are to cause the programmable circuitry to determine a chamber pressure within a chamber in which the pneumatic nozzle is disposed, and cause adjustment to a fourth valve associated with a chamber outlet based on the chamber pressure within the chamber.

Example 13 includes the non-transitory machine readable storage medium of example 8, wherein the first liquid having a first temperature, the second liquid having a second temperature higher than the first temperature, the superheated vapor having a third temperature higher than the second temperature.

Example 14 includes the non-transitory machine readable storage medium of example 8, wherein the instructions are to cause the programmable circuitry to determine the condition of the fluid to be dispensed by the pneumatic nozzle based on a saturation temperature of the first and second liquids in a chamber containing the pneumatic nozzle.

Example 15 includes a method comprising determining, by executing a machine readable instruction with programmable circuitry, a condition of a fluid to be dispensed by a pneumatic nozzle, the condition of the fluid including a temperature of the fluid, determining, by executing a machine readable instruction with programmable circuitry, a ratio of a first liquid, a second liquid, and a superheated vapor that combine to result in the condition of the fluid, and causing, by executing a machine readable instruction with programmable circuitry, the first liquid, the second liquid, and the superheated vapor to be provided to the pneumatic nozzle in proportions defined by the ratio.

Example 16 includes the method of example 15, wherein the determining of the condition of the fluid based on a first temperature associated with a semiconductor device and a second temperature associated with a semiconductor device, the first temperature being an operating temperature of the semiconductor device, the second temperature being a target temperature of the semiconductor device.

Example 17 includes the method of example 15, wherein the causing of the proportions of the first liquid, the second liquid, and the superheated vapor provided to the pneumatic nozzle includes causing adjustment of at least one of a first valve associated with the first liquid, a second valve associated with the second liquid, or a third valve associated with the superheated vapor.

Example 18 includes the method of example 17, further including causing the first valve associated with the first liquid and the second valve associated with the second liquid to close to cut-off a liquid supply to the pneumatic nozzle.

Example 19 includes the method of example 17, further including determining a chamber pressure within a chamber in which the pneumatic nozzle is disposed, and causing adjustment to a fourth valve associated with a chamber outlet based on the chamber pressure within the chamber.

Example 20 includes the method of example 15, wherein the first liquid having a first temperature, the second liquid having a second temperature higher than the first temperature, the superheated vapor having a third temperature higher than the second temperature.

Example 21 includes the method of example 15, wherein the determining of the condition of the fluid to be dispensed by the pneumatic nozzle based on a saturation temperature of the first and second liquids in a chamber containing the pneumatic nozzle.

Example 22 includes an apparatus comprising a pneumatic nozzle, a first valve fluidly coupled to a first conduit, the first conduit fluidly coupled to the pneumatic nozzle, the first conduit to transport a first liquid having a first temperature, a second valve fluidly coupled to a second conduit, the second conduit fluidly coupled to the pneumatic nozzle, the second conduit to transport a second liquid having a second temperature higher than the first temperature, a third valve fluidly coupled to a third conduit, the second conduit fluidly coupled to the pneumatic nozzle, the third conduit to transport a gas, the pneumatic nozzle to cause the gas to produce an atomized spray of a combination of the first and second liquids, and control circuitry to control operation of the first valve, the second valve, and the third valve to adjust a third temperature of the atomized spray.

Example 23 includes the apparatus of example 22, wherein the third temperature of the atomized spray is to be above a saturation temperature upon enter a chamber in which the pneumatic nozzle is positioned.

Example 24 includes the apparatus of example 22, wherein the first and second conduits are fluidly coupled to an inlet of the pneumatic nozzle.

Example 25 includes the apparatus of example 22, wherein the first and second liquids are water, and the gas is superheated water vapor.

Example 26 includes the apparatus of example 22, wherein the pneumatic nozzle is to mix the first liquid and the second liquid into the combination of the first and second liquids.

Example 27 includes the apparatus of example 22, wherein the gas is to have a fourth temperature higher than the second temperature so that gas is to increase the third temperature of the combination of the first and second liquids relative to the third temperature before being dispense out the pneumatic nozzle as the atomized spray.

Example 28 includes an apparatus comprising a housing defining a chamber in which an IC package is to be disposed, a nozzle disposed in the chamber, the nozzle to be directed towards the IC package, a first duct to transport a first proportion of a liquid to the nozzle, a second duct to transport a second proportion of the liquid to the nozzle, the second proportion of the liquid at a different temperature than the first proportion of the liquid, and a second duct to transport a vapor to the nozzle, the nozzle to combine the vapor with the first and second proportions of the liquid to produce an atomized spray onto the IC package.

Example 29 includes the apparatus of example 28, further including a first valve to control at least one of a flow rate or a volume of the first proportion of the liquid to the nozzle, and a second valve to control at least one of a flow rate or a volume of the second proportion of the liquid to the nozzle.

Example 30 includes the apparatus of example 28, further including a third valve to control at least one of a flow rate or a volume of the vapor to the nozzle.

Example 31 includes the apparatus of example 28, wherein the nozzle is to dispense the vapor into the chamber without the atomized spray when the first and second valves are closed.

Example 32 includes the apparatus of example 28, wherein the chamber includes an outlet, the outlet fluidly coupled to a fourth valve to adjust an amount of pressure in the chamber.

Example 33 includes the apparatus of example 28, wherein the nozzle is a pneumatic nozzle.

Example 34 includes the apparatus of example 28, wherein the vapor provided to the nozzle includes vapor removed from the chamber.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

1. An apparatus comprising:
interface circuitry;
machine readable instructions; and
programmable circuitry to at least one of instantiate or execute the machine readable instructions to:
determine a condition of a fluid to be dispensed by a pneumatic nozzle, the condition of the fluid including a temperature of the fluid;
determine a ratio of a first liquid, a second liquid, and a superheated vapor that combine to result in the condition of the fluid; and
cause the first liquid, the second liquid, and the superheated vapor to be provided to the pneumatic nozzle in proportions defined by the ratio.

2. The apparatus of claim 1, wherein the programmable circuitry is to determine the condition of the fluid based on a first temperature associated with a semiconductor device and a second temperature associated with a semiconductor device, the first temperature being an operating temperature of the semiconductor device, the second temperature being a target temperature of the semiconductor device.

3. The apparatus of claim 1, wherein the programmable circuitry is to control the proportions of the first liquid, the second liquid, and the superheated vapor provided to the pneumatic nozzle by causing adjustment of at least one of a first valve associated with the first liquid, a second valve associated with the second liquid, or a third valve associated with the superheated vapor.

4. The apparatus of claim 3, wherein the programmable circuitry is to cause the first valve associated with the first liquid and the second valve associated with the second liquid to close to cut-off a liquid supply to the pneumatic nozzle.

5. The apparatus of claim 3, wherein the programmable circuitry is to:
determine a chamber pressure within a chamber in which the pneumatic nozzle is disposed; and
cause adjustment to a fourth valve associated with a chamber outlet based on the chamber pressure within the chamber.

6. The apparatus of claim 1, wherein the first liquid having a first temperature, the second liquid having a second temperature higher than the first temperature, the superheated vapor having a third temperature higher than the second temperature.

7. The apparatus of claim 1, wherein the programmable circuitry is to determine the condition of the fluid to be dispensed by the pneumatic nozzle based on a saturation temperature of the first and second liquids in a chamber containing the pneumatic nozzle.

8. A non-transitory machine readable storage medium comprising instructions to cause programmable circuitry to at least:
determine a condition of a fluid to be dispensed by a pneumatic nozzle, the condition of the fluid including a temperature of the fluid;
determine a ratio of a first liquid, a second liquid, and a superheated vapor that combine to result in the condition of the fluid; and
cause the first liquid, the second liquid, and the superheated vapor to be provided to the pneumatic nozzle in proportions defined by the ratio.

9. The non-transitory machine readable storage medium of claim 8, wherein the instructions are to cause the programmable circuitry to determine the condition of the fluid based on a first temperature associated with a semiconductor device and a second temperature associated with a semiconductor device, the first temperature being an operating temperature of the semiconductor device, the second temperature being a target temperature of the semiconductor device.

10. The non-transitory machine readable storage medium of claim 8, wherein the instructions are to cause the programmable circuitry to control the proportions of the first liquid, the second liquid, and the superheated vapor provided to the pneumatic nozzle by causing adjustment of at least one of a first valve associated with the first liquid, a second valve associated with the second liquid, or a third valve associated with the superheated vapor.

11. The non-transitory machine readable storage medium of claim 10, wherein the instructions are to cause the programmable circuitry to cause the first valve associated with the first liquid and the second valve associated with the second liquid to close to cut-off a liquid supply to the pneumatic nozzle.

12. The non-transitory machine readable storage medium of claim 10, wherein the instructions are to cause the programmable circuitry to:
determine a chamber pressure within a chamber in which the pneumatic nozzle is disposed; and
cause adjustment to a fourth valve associated with a chamber outlet based on the chamber pressure within the chamber.

13. The non-transitory machine readable storage medium of claim 8, wherein the first liquid having a first temperature, the second liquid having a second temperature higher than the first temperature, the superheated vapor having a third temperature higher than the second temperature.

14. The non-transitory machine readable storage medium of claim 8, wherein the instructions are to cause the programmable circuitry to determine the condition of the fluid to be dispensed by the pneumatic nozzle based on a saturation temperature of the first and second liquids in a chamber containing the pneumatic nozzle.

15-21. (canceled)

22. An apparatus comprising:
a pneumatic nozzle;
a first valve fluidly coupled to a first conduit, the first conduit fluidly coupled to the pneumatic nozzle, the first conduit to transport a first liquid having a first temperature;
a second valve fluidly coupled to a second conduit, the second conduit fluidly coupled to the pneumatic nozzle, the second conduit to transport a second liquid having a second temperature higher than the first temperature;
a third valve fluidly coupled to a third conduit, the second conduit fluidly coupled to the pneumatic nozzle, the third conduit to transport a gas, the pneumatic nozzle to cause the gas to produce an atomized spray of a combination of the first and second liquids; and
control circuitry to control operation of the first valve, the second valve, and the third valve to adjust a third temperature of the atomized spray.

23. The apparatus of claim 22, wherein the third temperature of the atomized spray is to be above a saturation temperature upon enter a chamber in which the pneumatic nozzle is positioned.

24. The apparatus of claim 22, wherein the first and second conduits are fluidly coupled to an inlet of the pneumatic nozzle.

25. The apparatus of claim 22, wherein the first and second liquids are water, and the gas is superheated water vapor.

26. The apparatus of claim 22, wherein the pneumatic nozzle is to mix the first liquid and the second liquid into the combination of the first and second liquids.

27. The apparatus of claim 22, wherein the gas is to have a fourth temperature higher than the second temperature so that gas is to increase the third temperature of the combination of the first and second liquids relative to the third temperature before being dispense out the pneumatic nozzle as the atomized spray.

28-34. (canceled)
